(19) United States
(12) Patent Application Publication
(10) Pub. No.: US 2025/0351369 A1
(43) Pub. Date: Nov. 13, 2025

(54) SEMICONDUCTOR DEVICE

(71) Applicant: Samsung Electronics Co., Ltd., Suwon-si (KR)

(72) Inventors: Kwangsoo Kim, Suwon-si (KR); Suseong Noh, Suwon-si (KR); Ilho Myeong, Suwon-si (KR)

(21) Appl. No.: 19/089,107

(22) Filed: Mar. 25, 2025

(30) Foreign Application Priority Data
May 8, 2024 (KR) 10-2024-0060281

(51) Int. Cl. H10B 51/30; H10B 51/20

(52) U.S. Cl. CPC H10B 51/30; H10B 51/20

(57) ABSTRACT

A semiconductor device may include a channel layer on a substrate, a first interface insulation layer and a ferroelectric layer sequentially stacked on the channel layer, a nitride charge trapping layer contacting the ferroelectric layer, and a gate pattern disposed on the nitride charge trapping layer. The nitride charge trapping layer may include at least silicon and nitrogen. The nitride charge trapping layer may have a concentration of silicon that varies depending on a position within the nitride charge trapping layer.

### CROSS-REFERENCE TO RELATED APPLICATION

This application claims priority under 35 USC § 119 to Korean Patent Application No. 10-2024-0060281, filed on May 8, 2024, in the Korean Intellectual Property Office (KIPO), the contents of which are incorporated by reference herein in their entirety.

### BACKGROUND

Various example embodiments relate to a semiconductor device. Particularly, various example embodiments relate to a vertical memory device in which memory cells are stacked in a vertical direction.

In order to achieve high integration of a semiconductor device, a vertical memory device in which memory cells are stacked in the vertical direction may be presented. In the vertical memory device, a structure including a ferroelectric material in each of the memory cells may be developed.

### SUMMARY

Various example embodiments provide a semiconductor device including memory cells having excellent operating characteristics.

According to some example embodiments, a semiconductor device may include a channel layer on a substrate, a first interface insulation layer and a ferroelectric layer sequentially stacked on the channel layer, a nitride charge trapping layer contacting the ferroelectric layer, and a gate pattern disposed on the charge trapping nitride layer. The nitride charge trapping layer may include at least silicon and nitrogen. The nitride charge trapping layer may have a concentration of silicon that varies depending on a position within the nitride charge trapping layer.

According to some example embodiments, there is provided a semiconductor device. The semiconductor device may include a source line on a substrate, a channel layer on the source line, a first interface insulation layer and a ferroelectric layer sequentially stacked on sidewalls of the channel layer, a nitride charge trapping layer contacting a surface of the ferroelectric layer, a second interface insulation layer on a surface of the nitride charge trapping layer, and a plurality of gate patterns on a surface of the second interface insulation layer. The nitride charge trapping layer may include at least silicon and nitrogen. The nitride charge trapping layer may have a concentration of silicon that varies depending on a position within the nitride charge trapping layer. The plurality of gate patterns may be spaced apart from each other in a vertical direction perpendicular to an upper surface of the substrate. The nitride charge trapping layer may have a concentration of silicon that varies depending on a position within the nitride charge trapping layer.

According to some example embodiments, there is provided a semiconductor device. The semiconductor device may include a source line on a substrate, a channel layer on the source line, a first interface insulation layer and a ferroelectric layer sequentially stacked on the channel layer, a nitride charge trapping layer contacting a surface of the ferroelectric layer, a second interface insulation layer on a surface of the nitride charge trapping layer, and a plurality of gate patterns on the surface of the second interface insulation layer. The channel layer may include a vertical extension extending in a vertical direction perpendicular to a surface of the substrate. The first interface insulation layer and a ferroelectric layer sequentially stacked on at least a portion of a sidewall of the vertical extension of the channel layer in a horizontal direction parallel to the surface of the substrate. The plurality of gate patterns may be spaced apart from each other in a vertical direction perpendicular to the surface of the substrate. A portion of the nitride charge trapping layer adjacent to an interface between the nitride charge trapping layer and the ferroelectric layer may have a highest silicon concentration. A silicon concentration within the nitride charge trapping layer may gradually decrease as distance from the ferroelectric layer increases.

In the semiconductor device according to example embodiments, the memory cell may have a great difference between threshold voltages depending on data stored in the memory cell. Therefore, a memory window of the memory cell may be increased. Additionally, the memory cell may have good data retention characteristic. Therefore, the semiconductor device may have excellent operating characteristics.

### BRIEF DESCRIPTION OF THE DRAWINGS

Various example embodiments will be more clearly understood from the following detailed description taken in conjunction with the accompanying drawings.

FIGS. 1 to 25 represent various non-limiting, example embodiments as described herein.

FIG. 1 is a cross-sectional view illustrating a vertical semiconductor device according to example embodiments;

FIG. 2 is a plan view of memory cells in a vertical semiconductor device according to example embodiments;

FIG. 3 is a cross-sectional view illustrating a portion of a vertical semiconductor device according to example embodiments;

FIG. 4 is a cross-sectional view illustrating a portion of a vertical semiconductor device according to example embodiments;

FIG. 5 is a cross-sectional view for explaining the operation of a memory cell in a vertical semiconductor device according to example embodiments;

FIG. 6 is an energy band diagram of a memory cell in a vertical semiconductor device according to example embodiments;

FIG. 7 is a cross-sectional view illustrating a portion of a vertical semiconductor device according to some example embodiments;

FIGS. 8 to 16 are cross-sectional views illustrating a method of manufacturing a vertical semiconductor device according to example embodiments;

FIG. 17 is a cross-sectional view illustrating a vertical semiconductor device according to example embodiments;

FIGS. 18 and 19 are cross-sectional views illustrating a method of manufacturing a vertical semiconductor device according to example embodiments;

FIG. 20 is a cross-sectional view illustrating a vertical semiconductor device according to example embodiments;

FIG. 21 is a cross-sectional view illustrating a method of manufacturing a vertical semiconductor device according to example embodiments;

FIG. 22 is a cross-sectional view illustrating a vertical semiconductor device according to example embodiments;

FIG. 23 is a cross-sectional view illustrating a method of manufacturing a vertical semiconductor device according to example embodiments;

FIG. 24 is a perspective view illustrating a vertical semiconductor device according to example embodiments; and

FIG. 25 is a plan view illustrating a vertical semiconductor device according to example embodiments.

### DETAILED DESCRIPTION

Hereinafter, various example embodiments will be described in detail with reference to the accompanying drawings. In the following description, directions parallel to a surface of a substrate and perpendicular to each other are referred to as a first direction and a second direction, respectively. In addition, a direction perpendicular to the surface of the substrate is referred to as a vertical direction.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

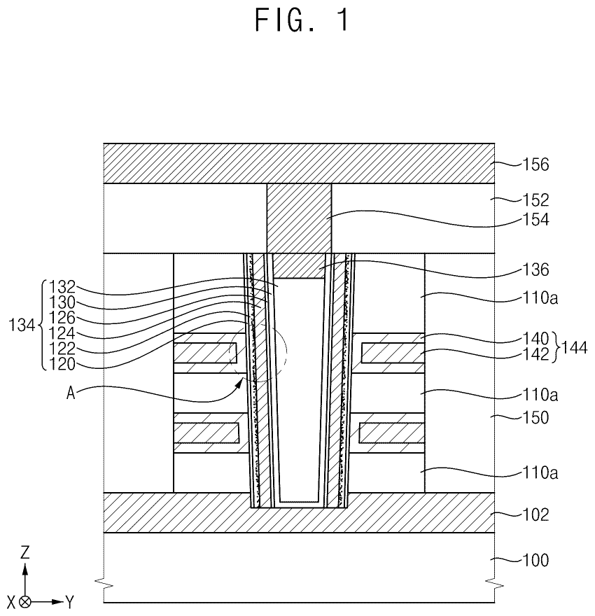

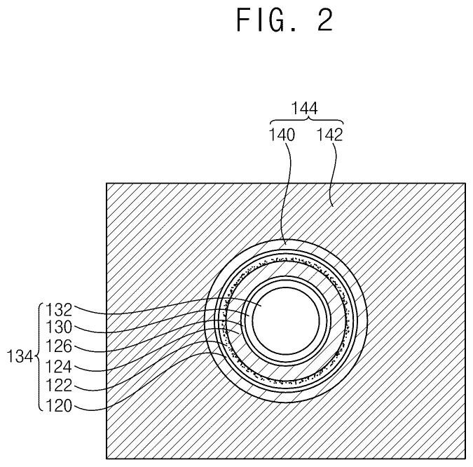

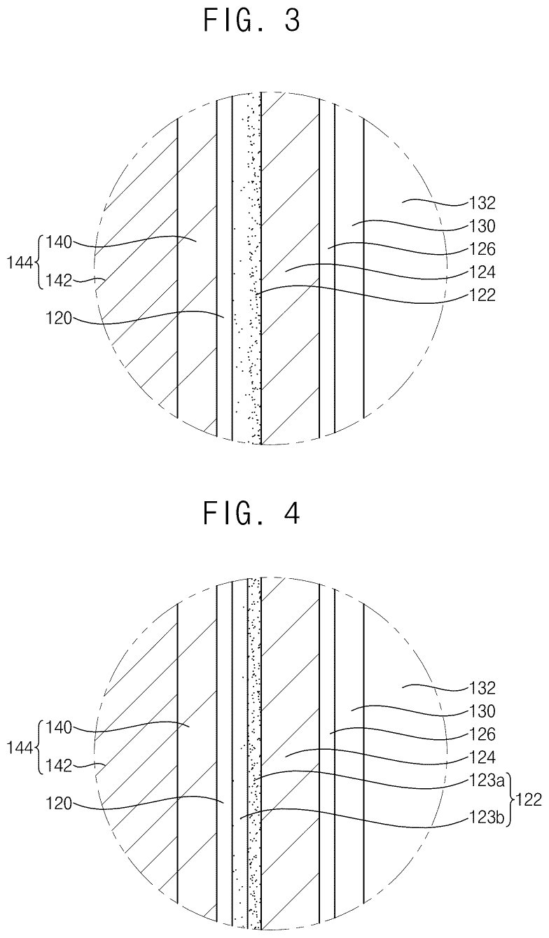

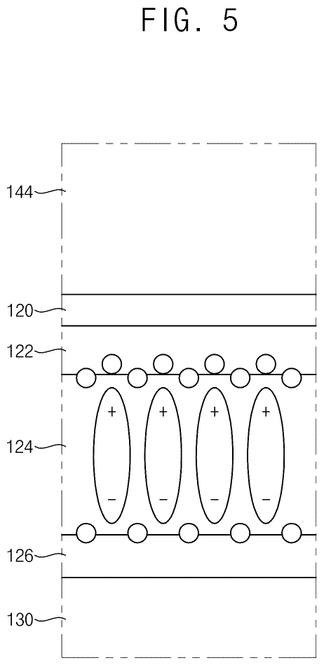

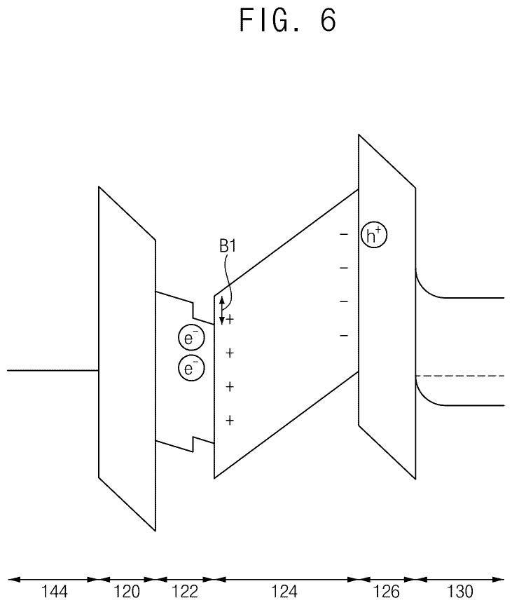

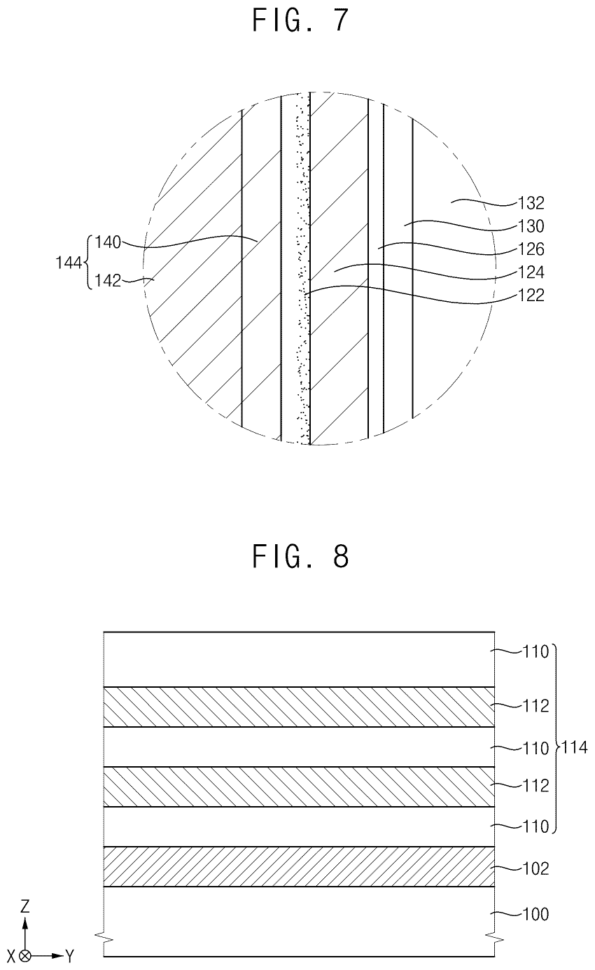

FIG. 1 is a cross-sectional view illustrating a vertical semiconductor device according to example embodiments. FIG. 2 is a plan view of memory cells in a vertical semiconductor device according to example embodiments. FIG. 3 is a cross-sectional view illustrating a portion of a vertical semiconductor device according to example embodiments. FIG. 4 is a cross-sectional view illustrating a portion of a vertical semiconductor device according to example embodiments. FIG. 5 is a cross-sectional view for explaining the operation of a memory cell in a vertical semiconductor device according to example embodiments. FIG. 6 is an energy band diagram of a memory cell in a vertical semiconductor device according to example embodiments. FIG. 7 is a cross-sectional view illustrating a portion of a vertical semiconductor device according to some example embodiments.

Each of FIGS. 3 and 4 is an enlarged cross-sectional view of a portion corresponding to A in FIG. 1.

Referring to FIGS. 1 to 4, the vertical semiconductor device may be formed on a substrate 100. A vertical semiconductor device, as described in connection with various figures herein, may refer to a memory cell or stack of memory cells, or may more generally refer to a semiconductor device such as a semiconductor chip formed on a die from a wafer. For example, a vertical semiconductor device may be a semiconductor memory chip having a three-dimensional memory cell array (e.g., vertical NAND, or VNAND). Various of the figures, such as FIG. 1, may depict only a portion of semiconductor device (e.g., one or more memory cells, or another portion of a semiconductor chip). The substrate 100 may include a semiconductor material such as silicon, germanium, or silicon-germanium, or a group III-V compound such as GaP, GaAs, or GaSb. In some example embodiments, the substrate 100 may be a silicon-on-insulator (SOI) substrate or a germanium-on-insulator (GOI) substrate.

A source line 102 may be on the substrate 100. The source line 102 may include, e.g., polysilicon doped with impurities, metal, conductive metal nitride, or metal silicide. In some example embodiments, the source line may not be formed, and the source line may be replaced with a source region doped with impurities at an upper portion of the substrate 100.

A stacked structure in which insulation layer patterns 110a and gate patterns 144 are alternately and repeatedly stacked may be disposed on the source line 102. The gate patterns 144 may extend in the first direction X, and the gate patterns 144 may serve as word lines in memory cells. An uppermost pattern of the stacked structure may be the insulation layer pattern 110a.

A channel structure 134 may pass through the stacked structure, and the channel structure 134 may extend to the source line 102. The channel structure 134 may include a first insulation structure 132, a channel layer 130, a first interface insulation layer 126, a ferroelectric layer 124, a trap nitride layer 122 (e.g., a charge trapping layer which may include a nitride such as silicon nitride or silicon oxynitride), and a second interface insulation layer 120. In some examples, the ferroelectric layer 124 and/or the trap nitride layer 122 may serve as data storage layers. In some examples, the presence of the ferroelectric layer 124 and/or the trap nitride layer (e.g., nitride charge trapping layer) 122 may enhance reliability and/or data retention of the vertical semiconductor device, e.g. by enhancing data retention of the memory cells. An upper conductive pattern 136 may be disposed on the channel structure 134.

An outer wall of the channel structure 134 may contact the gate patterns 144 and the insulation layer patterns 110a. The channel structure 134 and one of gate patterns 144 contacting the outer wall of the channel structure 134 may serve as one memory cell.

The channel structure 134 may have a pillar shape (e.g., a pillar shape with a filled interior). A bottom of the channel structure 134 may contact the source line 102.

The first insulation structure (e.g., first insulation pillar) 132 may have a pillar shape contacting an upper surface of the source line 102. In example embodiments, the first insulation structure 132 may include silicon oxide.

The channel layer 130 may surround a sidewall of the first insulation structure 132. The channel layer 130 may include, e.g., polysilicon, an oxide semiconductor, or a two-dimensional material. The oxide semiconductor may include, e.g., InxGayZnzO, InxSnyZnzO, InxZnyO, ZnxO, ZnxSnyO, ZnxOyN, ZrxZnySnzO, HfxInyZnzO, GaxZnySnzO, AlxZnySnzO, YbxGayZnzO, or a combination thereof. The two-dimensional material may include, e.g., MoS2, MoSe2, or WS2. A lower portion of the channel layer 130 may be electrically connected to the source line 102.

In example embodiments, the channel layer 130 may have a cylindrical shape (e.g., cup shape). In some example embodiments, the channel layer 130 may have a cylindrical shape having an open bottom. In some example embodiments, the first insulation structure 132 may not be formed, and in this case, the channel layer 130 may have a pillar shape with a filled interior. The channel layer 130 may include a vertical extension portion extending in the vertical direction Z.

The first interface insulation layer 126 may be on a surface of the channel layer 130. The first interface insulation layer 126 may be on a surface of the vertical extension portion of the channel layer 130. The first interface insulation layer 126 may include, e.g., silicon oxide or a metal oxide having a high dielectric constant.

The ferroelectric layer 124 may be on a surface of the first interface insulation layer 126. In example embodiments, the ferroelectric layer 124 and the first interface insulation layer 126 may contact each other. The first interface insulation layer 126 may be disposed on a surface of the ferroelectric layer 124 facing the channel layer 130.

In example embodiments, the ferroelectric layer 124 may include a hafnium oxide layer, a zirconium oxide layer, or a hafnium zirconium oxide layer. The ferroelectric layer 124 may have an orthorhombic phase. The ferroelectric layer 124 may include a dopant, and the dopant may include, e.g., silicon (Si), zirconium (Zr), aluminum (Al), yttrium (Y), lanthanum (La), or carbon (C), nitrogen (N), germanium (Ge), tin (Sn), strontium (Sr), lead (Pb), calcium (Ca), barium (Ba), titanium (Ti), zirconium (Zr), gadolinium (Gd), etc.

In some example embodiments, the ferroelectric layer 124 may include a ferroelectric material having a perovskite structure. For example, the ferroelectric layer 124 may include SrBi2Ta2O9, (Bi,La)4Ti3O12, or (Pb,Zr)TiO3.

The trap nitride layer 122 may be on the surface of the ferroelectric layer 124. The trap nitride layer 122 may contact the ferroelectric layer 124. The trap nitride layer 122 may be disposed on the surface of the ferroelectric layer 124 facing the gate pattern 144. The trap nitride layer 122 may be disposed between the ferroelectric layer 124 and the gate pattern 144. Additionally, the trap nitride layer 122 may not be disposed between the channel layer 130 and the ferroelectric layer 124. A distance between the ferroelectric layer 124 and the channel layer 130 is less than a distance between the trap nitride layer 122 and the channel layer 130. Accordingly, the ferroelectric layer 124 may be disposed closer to the channel layer 130, compared to the trap nitride layer 122.

The trap nitride layer 122 may include a material including at least silicon and nitrogen. The trap nitride layer 122 may include, e.g., silicon oxynitride or silicon nitride.

In the memory cell, the trap nitride layer 122 may serve as a layer for trapping charges so as to modify a threshold voltage of the memory cell, e.g. to represent a stored data bit.

A concentration of silicon included in the trap nitride layer 122 may vary with position within the trap nitride layer 122. Thus, the concentration of silicon included in the trap nitride layer 122 may have a gradient. Alternatively or additionally, in some examples, a concentration of nitrogen in the trap nitride layer 122 may vary with position within the trap nitride layer 122. For example, if the trap nitride layer 122 includes silicon nitride, the concentration of silicon and the concentration of nitrogen may vary. A concentration of silicon included in a layer or region refers to a proportional amount of silicon included in the layer or region.

An inner portion of the trap nitride layer 122 adjacent to the ferroelectric layer 124 may have a relatively high silicon concentration. In the inner portion of the trap nitride layer 122, the silicon concentration may decrease with distance from the ferroelectric layer 124. A portion of the trap nitride layer 122 adjacent to an interface between the trap nitride layer 122 and the ferroelectric layer 124 may have a highest silicon concentration. For example, a first portion of the trap nitride layer 122 adjacent to an interface between the trap nitride layer 122 and the ferroelectric layer 124 may include silicon rich silicon nitride, and the other portion except for the first portion of the trap nitride layer 122 may include silicon nitride. For example, a first portion of the trap nitride layer 122 adjacent to an interface between the trap nitride layer 122 and the ferroelectric layer 124 may include SixNy, and the other portion except for the first portion of the trap nitride layer 122 may include Six′Ny′, herein, x>x′.

In example embodiments, the silicon concentration within the trap nitride layer 122 may gradually decrease with distance (e.g., as distance increases) from the ferroelectric layer 124.

In some example embodiments, as shown in FIG. 4, the trap nitride layer 122 may include a first trap nitride sub-layer (e.g., a first nitride charge trapping sub-layer) 123a and a second trap nitride sub-layer (e.g., a second nitride charge trapping sub-layer) 123b. In some examples, the first trap nitride sub-layer may be referred to as a first trap nitride layer, and/or the second trap nitride sub-layer may be referred to as a second trap nitride layer. The first trap nitride sub-layer 123a may contact the ferroelectric layer 124, and may have a first silicon concentration. The second trap nitride sub-layer 123b may be disposed on the first trap nitride sub-layer 123a, and may not contact the ferroelectric layer 124. The second trap nitride sub-layer 123b may have a second silicon concentration lower than the first silicon concentration.

Therefore, the number of trap sites of the inner portion of the trap nitride layer 122 adjacent to the ferroelectric layer 124 may be greater than the number of trap sites of the inner portion of the trap nitride layer 122 adjacent to the gate pattern 144 (e.g., the inner portion of the trap nitride layer 122 adjacent to the second interface insulation layer 120).

In example embodiments, a thickness of the trap nitride layer 122 may be less than a thickness of the ferroelectric layer 124. For example, the thicknesses of the trap nitride layer 122 and ferroelectric layer 124 may be defined in horizontal directions parallel to the surface of the substrate, such as directions in the XY plane.

The second interface insulation layer 120 may be on a surface of the trap nitride layer 122. The second interface insulation layer 120 may include, e.g., silicon oxide or a metal oxide having a high dielectric constant.

The channel layer 130, the first interface insulation layer 126, the ferroelectric layer 124, the trap nitride layer 122, and the second interface insulation layer 120 may surround the sidewall of the first insulation structure 132.

The upper conductive pattern 136 may be disposed on the first insulation structure 132, and the upper conductive pattern 136 may contact an upper sidewall of the channel layer 130. The upper conductive pattern 136 may serve as a bit line pad.

Each of the gate patterns 144 may surround the channel structure 134, and the gate patterns 144 may extend in the first direction X. The gate patterns 144 may be on a sidewall of the channel structure 134 to be spaced apart from each other in the vertical direction Z.

Each of the gate patterns 144 may contact the second interface insulation layer 120. The gate patterns 144 may include a metal. In example embodiments, each of the gate patterns 144 may include a metal pattern 142 and a barrier metal pattern 140. The barrier metal pattern 140 may be conformally formed along an upper surface of the insulation layer pattern 110a, the sidewall of the channel structure 134, and a lower surface of the insulation layer pattern 110a. The barrier metal pattern 140 may surround a portion of a surface of the metal pattern 142.

An upper insulating interlayer 152 may be on the stacked structure, the channel structure 134, the first insulation structure 132, and the upper conductive pattern 136.

A bit line contact 154 may pass through the upper insulating interlayer 152, and the bit line contact 154 may contact the upper conductive pattern 136. A bit line 156 may be on the upper insulating interlayer 152 and the bit line contact 154. The bit line 156 may extend in the second direction Y. The bit line 156 may be electrically connected to the channel layer 130.

A unit memory cell included in the vertical semiconductor device may include the channel layer 130, the first interface insulation layer 126, the ferroelectric layer 124, the trap nitride layer 122, the second interface insulation layer 120 and the gate pattern 144 stacked on the sidewall of the first insulation structure 132 in a horizontal direction parallel to the surface of the substrate 100.

Referring to FIGS. 5 and 6, the unit memory cell may be operated by changing a dipole field of the ferroelectric layer 124 and/or by changing a number of charges trapped in trap sites of the trap nitride layer 122.

A threshold voltage of the unit memory cell may be changed by the dipole field (e.g., due to a polarization) of the ferroelectric layer 124, so that data may be written in the unit memory cell. Additionally, the data stored in the unit memory cell may be read by drain currents according to a voltage applied to the gate pattern of the unit memory cell. Therefore, the data stored in the unit memory cell may be determined according to a dipole direction (e.g., a polarization direction) of the ferroelectric layer 124.

FIGS. 5 and 6 show an erase state of the memory cell.

For example, the unit memory cell may have a first threshold voltage in a program state. The unit memory cell may have a second threshold voltage higher than the first threshold voltage in the erase state. When a verify voltage is applied to the gate pattern of a selected memory cell, data written in the selected memory cell may be read by the drain currents flowing through the selected memory cell.

When a write operation is performed in the unit memory cell, the dipole field (e.g., due to a polarization) of the ferroelectric layer 124 may be changed, and concurrently, charges may be trapped at trap sites in the trap nitride layer 122. The threshold voltage of the unit memory cell may additionally change due to the charges trapped at the trap sites, analogously to a conventional floating gate. As the trap nitride layer 122 is formed, a difference between the first threshold voltage and the second threshold voltage may be increased. Thus, the program state of the unit memory cell and the erase state of the unit memory cell may be more easily distinguished. Accordingly, as the trap nitride layer 122 is formed, a memory window (e.g., the difference between the first and second threshold voltages) of the unit memory cell may be increased.

As described above, the inner portion of the trap nitride layer 122 adjacent to the ferroelectric layer 124 may have a relatively high silicon concentration (e.g., the trap nitride layer 122 can have a concentration gradient of silicon and/or nitrogen), and thus the number (e.g., a volumetric density) of trap sites in the inner portion of the trap nitride layer 122 adjacent to the ferroelectric layer 124 may be increased. Additionally, when a voltage is applied into the gate pattern 144, charges moved from the gate pattern 144 to the trap nitride layer 122 may move to a portion with relatively low energy, e.g., the inner portion of the trap nitride layer 122 adjacent to the ferroelectric layer 124. Accordingly, the charges may be intensively trapped at the inner portion of the trap nitride layer 122 adjacent to the ferroelectric layer 124. The charges trapped in trap nitride layer 122 can modify the threshold voltage of the memory cell, for example when performing write, erase, and/or read, operations.

A strong dipole field may be generated at the ferroelectric layer 124, so that the charges trapped at the trap nitride layer 122 adjacent to the ferroelectric layer 124 may be held by the dipole field, and may not be lost. For example, a polarization of the ferroelectric layer 124 may generate the strong dipole field. Accordingly, a retention character of the data stored in the memory cell may be improved. In some examples, the polarization of the ferroelectric layer 124 may be varied. The dipole field generated by the ferroelectric layer 124 may also modify the threshold voltage of the memory cell, for example when performing write, erase, and/or read operations.

Additionally, the inner portion of the trap nitride layer 122 adjacent to the ferroelectric layer 124 may have a relatively high silicon concentration, so that an energy barrier B1 between the ferroelectric layer 124 and the trap nitride layer 122 may increase. For example, the presence of the silicon in the inner portion of the trap nitride layer 122 adjacent to the ferroelectric layer 124 may lower the energy gap in the inner portion, thereby raising the energy barrier B1 between the ferroelectric layer 124 and the trap nitride layer 122. Accordingly, movement (e.g., leakage or loss) of charges trapped at the trap nitride layer 122 into the ferroelectric layer 124 may be reduced.

Thus, due to the inner portion of trap nitride layer 122 having a higher silicon concentration (e.g., the trap nitride layer 122 having a silicon and/or nitrogen concentration gradient), more charges can be trapped around the portion of trap nitride layer 122 adjacent to the ferroelectric layer. Additionally, the trapped charges can be held by the dipole field generated at ferroelectric layer 124 adjacent to trap nitride layer 122, thereby reducing leakage and loss of the trapped charges. The disclosed memory cell can thereby improve a retention characteristic of data stored therein.

The unit memory cell may include the channel layer 130, the first interface insulation layer 126, the ferroelectric layer 124, the trap nitride layer 122, the second interface insulation layer 120, and the gate pattern 144 sequentially stacked. As the inner portion of the trap nitride layer 122 adjacent to the ferroelectric layer 124 has a relatively high silicon concentration, the operating characteristics (e.g., the retention characteristic of stored data) of the vertical semiconductor device may be improved.

It has been described that the layers included in the unit memory cell may be stacked in the horizontal direction on the sidewall of the channel layer extending in the vertical direction Z. However, a direction of stacking of the layer included in the unit memory cell may not be limited thereto. Similar to that shown in FIG. 5, the layers included in the unit memory cell may be stacked in the vertical direction on a horizontal surface of the channel layer. In this case, the unit memory cell may have a planar type.

A stacked structure of the unit memory cell may be modified.

In some example embodiments, as shown in FIG. 7, a unit memory cell in a vertical semiconductor device may include the channel layer 130, the first interface insulation layer 126, the ferroelectric layer 124, the trap nitride layer 122, and the gate pattern 144. That is, the second interface insulation layer may not be formed.

FIGS. 8 to 16 are cross-sectional views illustrating a method of manufacturing a vertical semiconductor device according to example embodiments.

Referring to FIG. 8, a source line 102 may be formed on the substrate 100. The source line 102 may be formed by depositing a first conductive layer and patterning the first conductive layer. The first conductive layer may be formed by, e.g., a chemical vapor deposition process or an atomic layer deposition process.

In example embodiments, lower circuit patterns constituting peripheral circuits may be further formed on the substrate 100, and then a lower insulating interlayer may be formed to cover the lower circuit patterns.

An insulation layer 110 and a sacrificial layer 112 may be alternately and repeatedly deposited on the source line 102 to form a mold structure 114. The sacrificial layer 112 may include an insulation material having a high etch selectivity with respect to a material of the insulation layer 110. In example embodiments, the insulation layer 110 may include silicon oxide, and the sacrificial layer 112 may include silicon nitride. The number of stacked insulation layers 110 and sacrificial layers 112 may not be limited. Memory cells may be formed at regions corresponding to the sacrificial layers 112 stacked in the vertical direction Z, respectively, by subsequent processes.

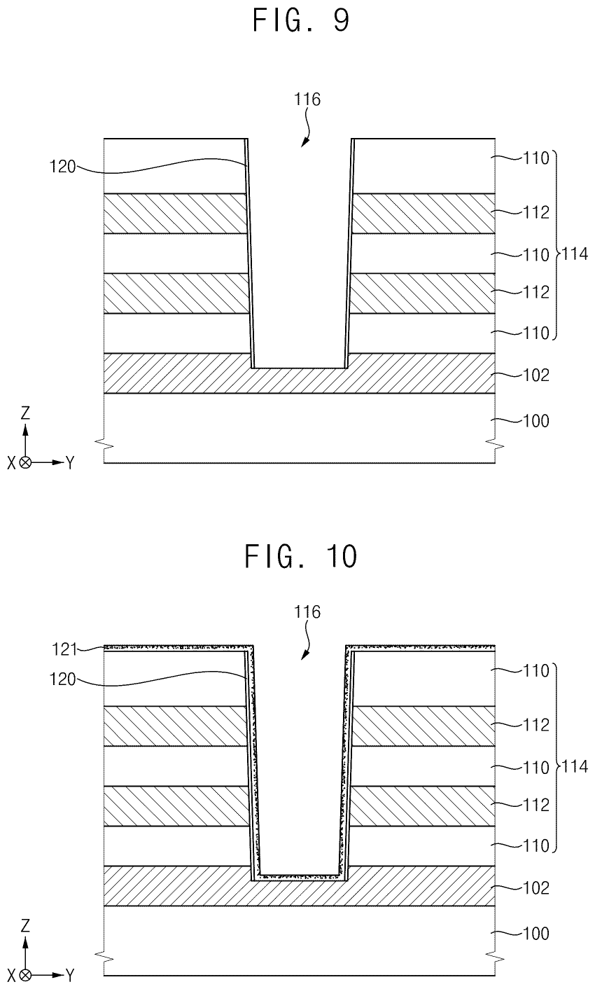

Referring to FIG. 9, the mold structure 114 including the insulation layers 110 and sacrificial layers 112 may be anisotropically etched to form a first hole passing through the mold structure 114 and exposing an upper portion of the source line 102. To avoid complexity of the drawing, only one first hole 116 is shown, but a plurality of first holes 116 may be formed in the mold structure 114. In example embodiments, the plurality of first holes 116 may be regularly arranged in each of the first direction X and the second direction Y.

The insulation layers 110 and the sacrificial layers 112 may be exposed by a sidewall of the first hole 116.

Thereafter, a second preliminary interface insulation layer may be conformally formed on the sidewall and a bottom of the first hole 116 and an upper surface of the mold structure 114. The second preliminary interface insulation layer may be anisotropically etched to form a second interface insulation layer 120 on the sidewall of the first hole 116.

Referring to FIG. 10, a preliminary trap nitride layer 121 may be conformally formed on the surface of the second interface insulation layer 120, the bottom of the first hole 116, and the mold structure 114.

The preliminary trap nitride layer 121 may be a material including at least silicon and nitrogen. The preliminary trap nitride layer 121 may include, e.g., silicon oxynitride or silicon nitride.

A concentration of the silicon included in the preliminary trap nitride layer 121 may vary with position within the preliminary trap nitride layer 121 (e.g., there may be a concentration gradient of the silicon included in the preliminary trap nitride layer 121). An inner portion of the preliminary trap nitride layer 121 adjacent to the second interface insulation layer 120 may have a low silicon concentration. In the preliminary trap nitride layer 121, the silicon concentration may increase with distance from the second interface insulation layer 120. An inner portion of the preliminary trap nitride layer 121 adjacent to a ferroelectric layer may have a relatively high silicon concentration. In the preliminary trap nitride layer 121, the silicon concentration may decrease with distance from the ferroelectric layer 124.

In an example of a method for forming the preliminary trap nitride layer 121, a first preliminary trap nitride layer may be formed on the second interface insulation layer 120, and then a nitride surface treatment may be performed on the first preliminary trap nitride layer. A second preliminary trap nitride layer may be formed on the first preliminary trap nitride layer. Therefore, the preliminary trap nitride layer 121 may have the first preliminary trap nitride layer and the second preliminary trap nitride layer. The inner portion of the preliminary trap nitride layer 121 adjacent to the ferroelectric layer 124 may have relatively high silicon concentration.

In some examples of a method for forming the preliminary trap nitride layer 121, a first preliminary trap nitride layer having a second silicon concentration may be formed on the second interface insulation layer 120, and then a second preliminary trap nitride layer having a first silicon concentration may be formed on the first preliminary trap nitride layer. Therefore, the preliminary trap nitride layer 121 may have the first preliminary trap nitride layer and the second preliminary trap nitride layer. In example embodiments, a process for forming the preliminary trap nitride layer 121 may include an atomic layer deposition process or a chemical vapor deposition process. For controlling the silicon concentration in the preliminary trap nitride layer 121, concentrations of nitrogen source gas and/or silicon source gas may be adjusted in the deposition process of the preliminary trap nitride layer 121.

Referring to FIG. 11, the preliminary trap nitride layer 121 may be anisotropically etched to form a trap nitride layer 122. The trap nitride layer 122 may be formed on surfaces of the second interface insulation layer 120.

In example embodiments, as shown in FIG. 3, an inner portion of the trap nitride layer 122 adjacent to the ferroelectric layer may have a relatively high silicon concentration, and a silicon concentration within the trap nitride layer 122 may be decreased with distance from the ferroelectric layer. In some example embodiments, as shown in FIG. 4, the trap nitride layer 122 may include a first trap nitride sub-layer (e.g., a first nitride charge trapping sub-layer) 123a adjacent to the ferroelectric layer and having the first silicon concentration and a second trap nitride sub-layer (e.g., a second nitride charge trapping sub-layer) 123b having the second silicon concentration lower than the first silicon concentration. In some examples, the first trap nitride sub-layer may be referred to as a first trap nitride layer, and/or the second trap nitride sub-layer may be referred to as a second trap nitride layer.

A preliminary ferroelectric layer may be conformally formed on a surface of the trap nitride layer 122, the bottom of the first hole 116, and the mold structure 114. The preliminary ferroelectric layer may be anisotropically etched to form a ferroelectric layer 124 on the surface of the trap nitride layer 122.

In example embodiments, a thickness of the ferroelectric layer 124 may be greater than the thickness of the trap nitride layer 122. For example, the thicknesses of the trap nitride layer 122 and ferroelectric layer 124 may be defined in horizontal directions parallel to the surface of the substrate, such as directions in the XY plane.

A first preliminary interface insulation layer may be conformally formed on the surface of the ferroelectric layer 124, the bottom of the first hole 116, and the mold structure 114. The first preliminary interface insulation layer may be anisotropically etched to form a first interface insulation layer 126 on the surface of the ferroelectric layer 124.

A preliminary channel layer 128 may be formed conformally on the surface of a first interface insulation layer 126, the bottom surface of the first hole 116, and the mold structure 114. Accordingly, the second interface insulation layer 120, the ferroelectric layer 124, the trap nitride layer 122, the first interface insulation layer 126, and the preliminary channel layer 128 may be sequentially stacked on the sidewall of the first hole 116.

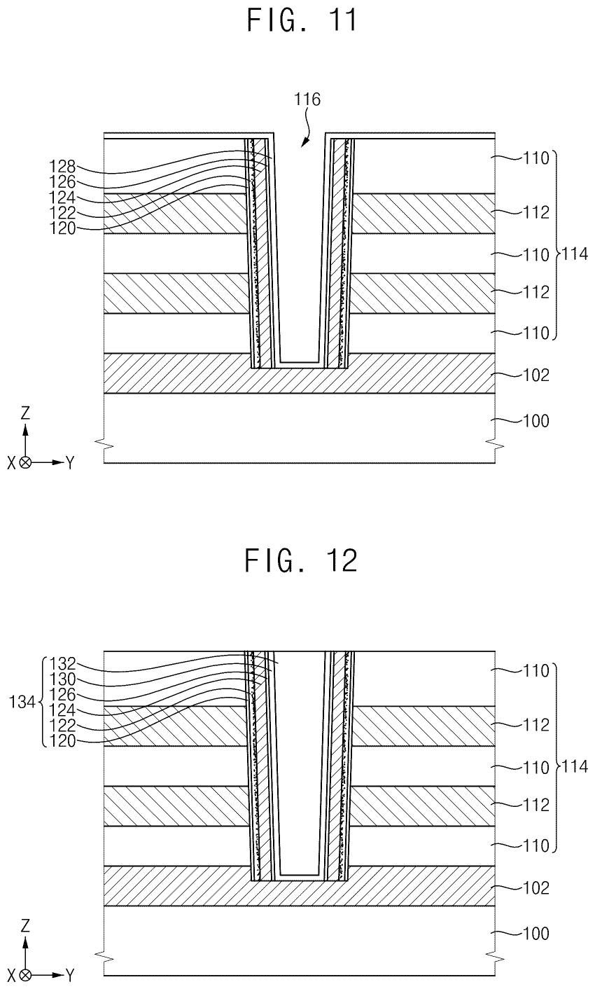

Referring to FIG. 12, a first insulation layer may be formed on the preliminary channel layer 128 to fill the first hole 116. Thereafter, the first insulation layer may be planarized until the upper surface of the mold structure 114 is exposed to form a first insulation structure 132. The planarization process may include a chemical mechanical polishing (CMP) process or an etch-back process. The first insulation structure 132 may fill the first hole 116. The second interface insulation layer 120, the ferroelectric layer 124, the trap nitride layer 122, the first interface insulation layer 126, and the channel layer 130 may surround a sidewall of the first insulation structure 132.

A stacked structure of the first insulation structure 132, the channel layer 130, the first interface insulation layer 126, the trap nitride layer 122, the ferroelectric layer 124, and the second interface insulation layer 120 is referred to as a channel structure 134. The channel structure 134 may extend in the vertical direction Z through the mold structure 114 to the source line 102. The channel layer 130 may be electrically connected to the source line 102.

Referring to FIG. 13, an upper portion of the first insulation structure 132 may be partially removed to form an upper recess. The channel layer 130 may be exposed by a sidewall of the upper recess. A conductive material may fill the upper recess to form an upper conductive pattern 136. The upper conductive pattern 136 may be electrically connected to the channel layer 130. The upper conductive pattern 136 may serve as a bit line pad for electrically connecting a bit line subsequently formed. In some example embodiments, the process for forming the upper conductive pattern 136 may be omitted.

A first trench 118 may be formed to pass through the mold structure 114, and the first trench 118 may extend to the upper portion of the source line 102. The first trench 118 may extend in the first direction X, and the first trench 118 may be spaced apart from the channel structure 134.

As the first trench 118 is formed, the insulation layers 110 and the sacrificial layers 112 may be converted into insulation layer patterns 110a and sacrificial layer patterns 112a, respectively. The insulation layer patterns 110a and the sacrificial layer patterns 112a may be exposed by a sidewall of the first trench 118.

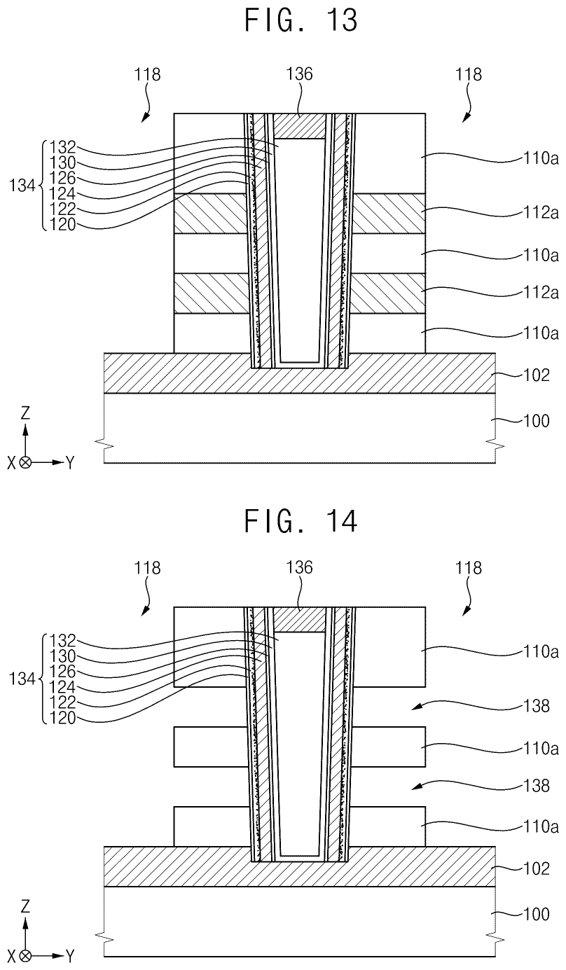

Referring to FIG. 14, the sacrificial layer patterns 112a exposed by the sidewall of the first trench 118 may be selectively removed. A selective removing process of the sacrificial layer patterns 112a may include an isotropic etching process. The insulation layer patterns 110a may remain on the sidewall of the channel structure 134, after the selective removing process of the sacrificial layer patterns 112a. The insulation layer patterns 110a may protrude from the sidewall of the channel structure 134. Additionally, a gap 138 may be formed between the insulation layer patterns 110a in the vertical direction Z.

An outer wall of the channel structure 134 (i.e., the second interface insulation layer 120) may be exposed by the gap 138.

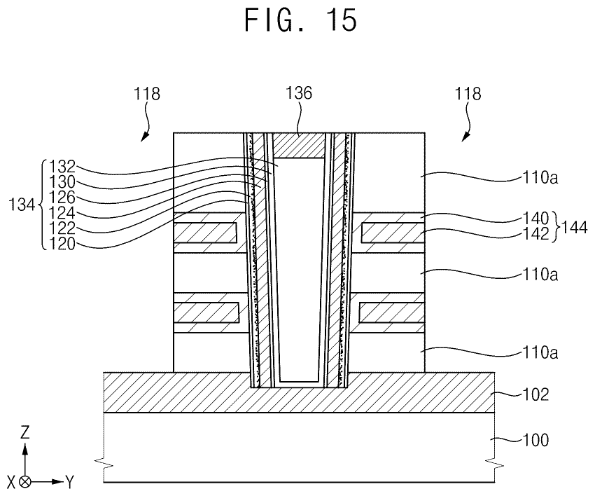

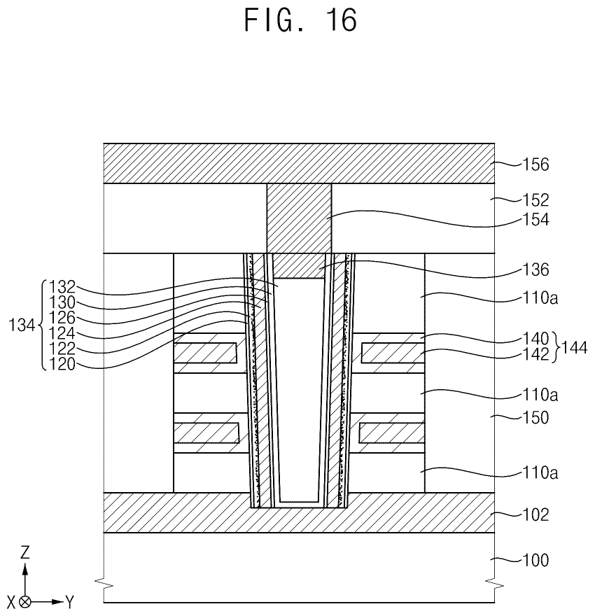

Referring to FIG. 15, a conductive material may be formed to fill the gap 138, so that a gate pattern 144 may be formed in the gap 138. The gate pattern 144 may include, e.g., a metal. The gate pattern 144 may include a barrier metal pattern 140 and a metal pattern 142.

In example embodiments, a barrier metal layer may be conformally formed on a surface of the gap 138, the first trench 118, the insulation layer pattern 110a, the channel structure 134, and the upper conductive pattern 136. A metal layer may be formed on the barrier metal layer to fill the gap 138. Thereafter, the metal layer and the barrier metal layer on the first trench 118, the insulation layer pattern 110a, the channel structure 134, and the upper conductive pattern 136 may be removed, so that a conductive layer may remain only in the gap. Accordingly, the gate pattern 144 may be formed in the gap 138. The gate pattern 144 may extend in the first direction X, and the gate pattern 144 serve as a word line. A partial removing process of the metal layer and the barrier metal layer may include an isotropic etching process, e.g., a wet etching process.

Referring to FIG. 16, a second insulation structure (e.g., second insulation pillar) 150 may be formed in the first trench 118. The second insulation structure 150 may include, e.g., silicon oxide or silicon nitride.

An upper insulating interlayer 152 may be formed on the second insulation structure 150, the insulation layer pattern 110a, the channel structure 134, and the upper conductive pattern 136. The upper insulating interlayer 152 may cover the second insulation structure 150, the insulation layer pattern 110a, the channel structure 134, and the upper conductive pattern 136.

A bit line contact 154 may be formed to pass through the upper insulating interlayer 152, and the bit line contact 154 may be electrically connected to the upper conductive pattern 136. A bit line 156 may be formed on the upper insulating interlayer 152 and the bit line contact 154. The bit line 156 may contact the bit line contact 154.

In some example embodiments, a process for forming the bit line contact may be omitted. In this case, a portion of the upper insulating interlayer 152 may be etched to form an upper trench exposing the upper conductive pattern 136, and a bit line 156 contacting the upper conductive pattern 136 may be formed in the upper trench.

By the above processes, a vertical semiconductor device may be manufactured.

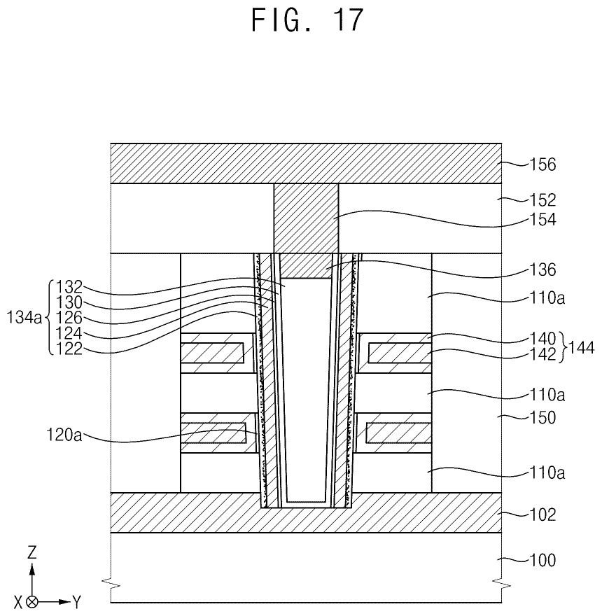

FIG. 17 is a cross-sectional view illustrating a vertical semiconductor device according to example embodiments.

The vertical semiconductor device may be the same as the vertical semiconductor device described with reference to FIG. 1, except for a stacked structure of layers included in a channel structure in a memory cell. Therefore, redundant descriptions may be omitted.

Referring to FIG. 17, a channel structure 134a may include the first insulation structure 132, the channel layer 130, the first interface insulation layer 126, the ferroelectric layer 124, and the trap nitride layer 122. A second interface insulation layer pattern 120a having a ring shape may surround the channel structure 134a.

An inner portion of the trap nitride layer 122 adjacent to the ferroelectric layer 124 may have a relatively high silicon concentration. The silicon concentration within the trap nitride layer 122 may decrease with distance from the ferroelectric layer 124.

A plurality of second interface insulation layer patterns 120a may be on the sidewall of the channel structure 134a, and the plurality of second interface insulation layer patterns 120a may be spaced apart from each other in the vertical direction Z. The plurality of second interface insulation layer patterns 120a may be provided on the surface of the trap nitride layer 122 while being spaced apart from each other in the vertical direction Z.

The second interface insulation layer patterns 120a may be arranged to face the gate pattern 144 in the horizontal direction, respectively. The second interface insulation layer pattern 120a may be disposed between the gate pattern 144 and the trap nitride layer 122, and may not be disposed between the insulation layer pattern 110a and the trap nitride layer 122. The second interface insulation layer pattern 120a and the insulation layer pattern 110a may be formed on the outer wall of the trap nitride layer 122.

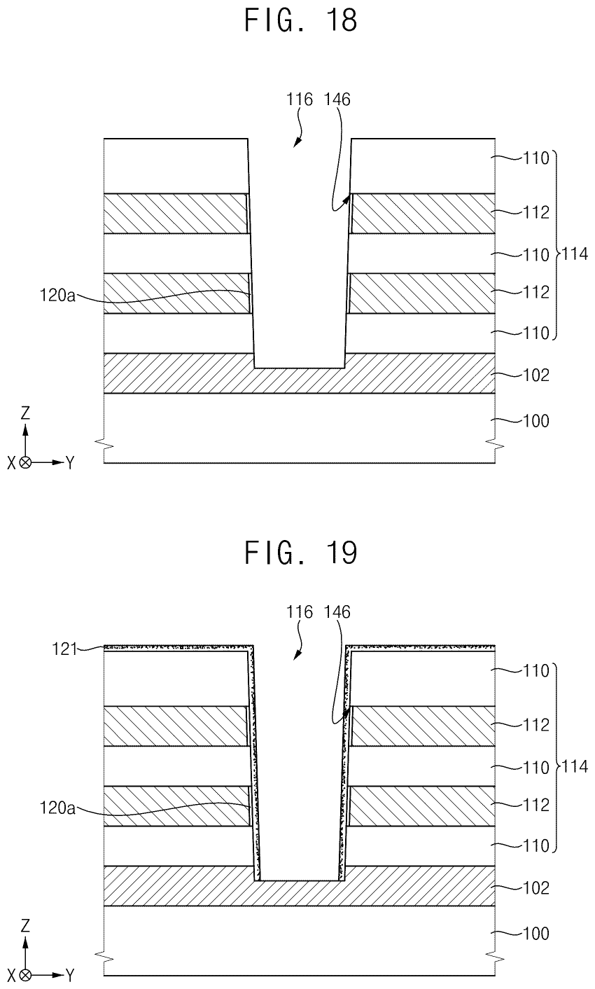

FIGS. 18 and 19 are cross-sectional views illustrating a method of manufacturing a vertical semiconductor device according to example embodiments.

Referring to FIG. 18, first, the process described with reference to FIG. 8 may be performed. Thereafter, the mold structure 114 on which the insulation layers 110 and the sacrificial layers 112 are alternately stacked may be anisotropically etched to form a first hole passing through the mold structure 114 and exposing an upper portion of the source line 102.

The sacrificial layers 112 exposed by the sidewall of the first hole 116 may be partially etched to form recesses 146 communicating with the sidewall of the first hole 116. A second interface insulation layer pattern 120a may be formed to fill each of the recesses 146.

Referring to FIG. 19, a preliminary trap nitride layer 121 may be formed on the second interface insulation layer patterns 120a and the insulation layers 110. The process for forming the preliminary trap nitride layer 121 may be substantially the same as that described with reference to FIG. 10.

Processes substantially the same as those described with reference to FIGS. 11 to 16 may be performed to manufacture the vertical semiconductor device shown in FIG. 17.

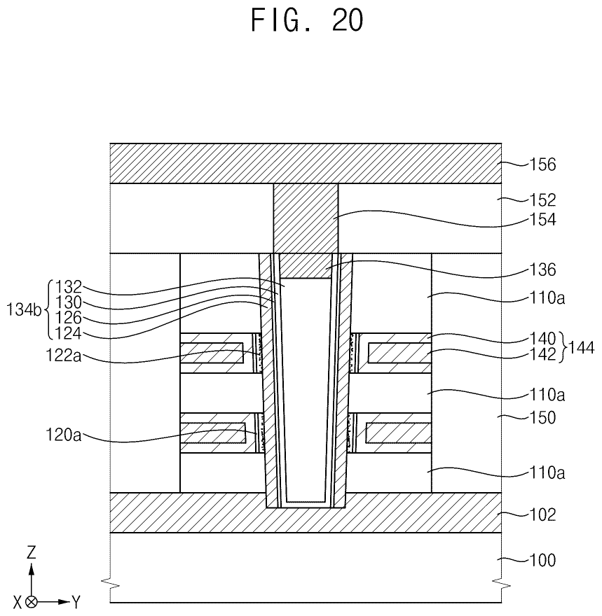

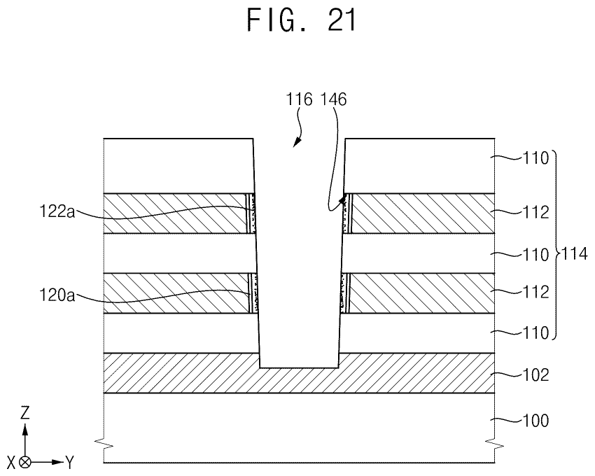

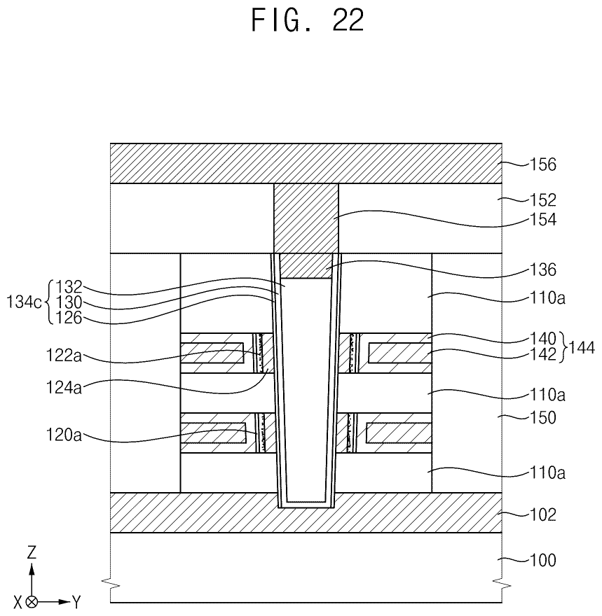

FIG. 20 is a cross-sectional view illustrating a vertical semiconductor device according to example embodiments.

The vertical semiconductor device may be the same as the vertical semiconductor device described with reference to FIG. 1, except for a stacked structure of a channel structure in a memory cell. Therefore, redundant descriptions may be omitted.

Referring to FIG. 20, the channel structure 134b may include the first insulation structure 132, the channel layer 130, the first interface insulation layer 126, and the ferroelectric layer 124. A trap nitride layer pattern 122a and a second interface insulation layer pattern 120a may have ring shapes, and may surround the channel structure 134b. The trap nitride layer pattern 122a and the second interface insulation layer pattern 120a may be stacked in the horizontal direction on the surface of the ferroelectric layer 124.

In the trap nitride layer pattern 122a, a portion adjacent to the ferroelectric layer 124 may have a relatively high silicon concentration. The silicon concentration within the trap nitride layer pattern 122a may gradually decrease with distance (e.g., as distance increases) from the ferroelectric layer 124.

A plurality of stacks including the trap nitride layer patterns 122a and the second interface insulation layer pattern 120a may be on the sidewall of the channel structure 134b to be spaced apart from each other in the vertical direction Z. The plurality of stacks including the trap nitride layer patterns 122a and the second interface insulation layer pattern 120a may be arranged to face the gate patterns 144 in the horizontal direction, respectively. The stack including the trap nitride layer pattern 122a and the second interface insulation layer pattern 120a may be disposed between the gate pattern 144 and the ferroelectric layer 124, and may not be disposed between the insulation layer pattern 110a and the ferroelectric layer 124. The trap nitride layer pattern 122a and the insulation layer pattern 110a may be disposed on an outer wall of the ferroelectric layer 124.

FIG. 21 is a cross-sectional view illustrating a method of manufacturing a vertical semiconductor device according to example embodiments.

Referring to FIG. 21, first, the process described with reference to FIG. 18 may be performed to form the first hole 116 and the recesses 146.

A second interface insulation layer pattern 120a and a trap nitride layer pattern 122a may be sequentially formed to fill each of the recesses 146.

In the trap nitride layer pattern 122a, a portion adjacent to the ferroelectric layer 124 may have a relatively high silicon concentration. The silicon concentration within the trap nitride layer pattern 122a may gradually decrease with distance (e.g., as distance increases) from the ferroelectric layer 124.

In example embodiments, a preliminary trap nitride layer pattern may be formed in each of the recesses 146, and then a surface nitridation treatment process may be performed on the preliminary trap nitride layer pattern to form the trap nitride layer pattern 122a.

Referring to FIG. 20 again, a ferroelectric layer 124, a first interface insulation layer 126, and a preliminary layer may be sequentially formed on the sidewall of the first hole 116 to cover the trap nitride layer patterns 122a and the insulation layers 110 exposed by the first hole 116. Thereafter, processes substantially the same as those described with reference to FIGS. 12 to 16 may be performed to manufacture the vertical semiconductor device shown in FIG. 20.

FIG. 22 is a cross-sectional view illustrating a vertical semiconductor device according to example embodiments.

The vertical semiconductor device may be the same as the vertical semiconductor device described with reference to FIG. 1, except for a stacked structure of a channel structure in a memory cell. Therefore, redundant descriptions are omitted.

Referring to FIG. 22, a channel structure 134c may include the first insulation structure 132, the channel layer 130, and the first interface insulation layer 126. A ferroelectric layer pattern 124a, a trap nitride layer pattern 122a, and a second interface insulation layer pattern 120a having ring shapes may surround the channel structure 134c. The ferroelectric layer pattern 124a, the trap nitride layer pattern 122a, and the second interface insulation layer pattern 120a may be stacked on a surface of the first interface insulation layer 126 in the horizontal direction.

An inner portion of the trap nitride layer pattern 122a adjacent to the ferroelectric layer pattern 124a may have a relatively high silicon concentration. The silicon concentration within the trap nitride layer pattern 122a may gradually decrease with distance (e.g., as distance increases) from the ferroelectric layer 124.

A plurality of stacks including the ferroelectric layer pattern 124a, the trap nitride layer pattern 122a, and the second interface insulation layer pattern 120a may be on a sidewall of the channel structure 134c to be spaced apart from each other in the vertical direction Z. The plurality of stacks including the ferroelectric layer pattern 124a, the trap nitride layer pattern 122a, and the second interface insulation layer pattern 120a may be arranged to face the gate patterns 144 in the horizontal direction, respectively.

The stack including the ferroelectric layer pattern 124a, the trap nitride layer pattern 122a, and the second interface insulation layer pattern 120a may be disposed between the gate pattern 144 and the first interface insulation layer 126. The stacks including the ferroelectric layer pattern 124a, the trap nitride layer pattern 122a, and the second interface insulation layer pattern 120a may not be disposed between the insulation layer pattern 110a and the first interface insulation layers 126. The ferroelectric layer pattern 124a, the trap nitride layer pattern 122a, and the insulation layer pattern 110a may be formed on the outer wall of the first interface insulation layer 126.

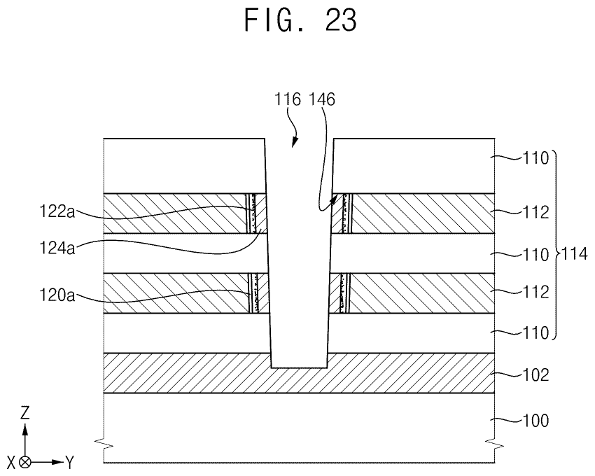

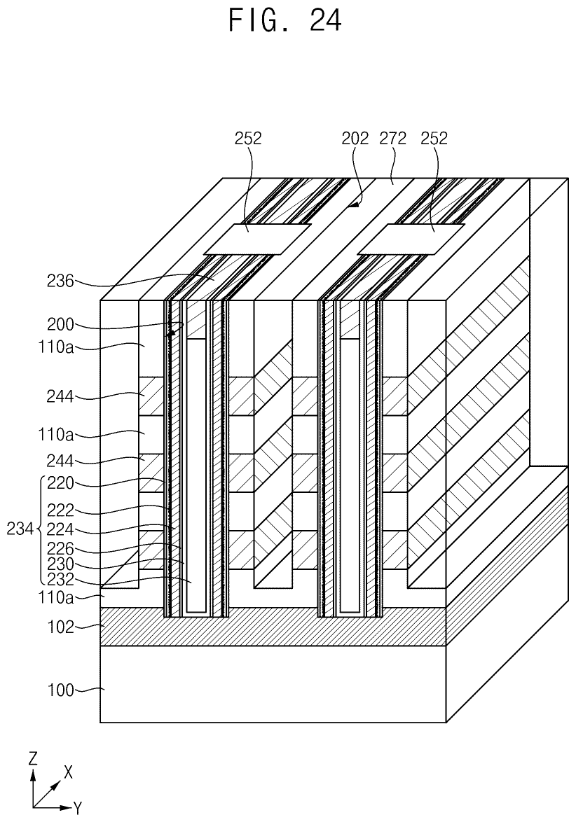

FIG. 23 is a cross-sectional view illustrating a method of manufacturing a vertical semiconductor device according to example embodiments.

Referring to FIG. 23, first, the process described with reference to FIG. 18 may be performed to form the first hole and recesses 146.

Thereafter, a second interface insulation layer pattern 120a, a trap nitride layer pattern 122a, and a ferroelectric layer pattern 124a may be sequentially formed to fill each of the recesses 146. The second interface insulation layer pattern 120a, the trap nitride layer pattern 122a, and the ferroelectric layer pattern 124a may be stacked in the horizontal direction.

An inner portion of the trap nitride layer pattern 122a adjacent to the ferroelectric layer pattern 124a may have a relatively high silicon concentration. The silicon concentration within the trap nitride layer pattern 122a may gradually decrease with distance (e.g., as distance increases) from the ferroelectric layer pattern 124a.

In example embodiments, a preliminary trap nitride layer pattern may be formed in each of the recesses 146, and then a surface nitridation treatment process may be performed on the preliminary trap nitride layer pattern to form the trap nitride layer pattern 122a.

Referring to FIG. 22 again, a first interface insulation layer 126 and a preliminary channel layer may be sequentially formed on the sidewall of the first hole 116 to cover the ferroelectric layer patterns 124a and the insulation layers 110 exposed by the first hole 116.

Thereafter, processes substantially the same as described with reference to FIG. 12 to 16 may be performed to manufacture the vertical semiconductor device shown in FIG. 22.

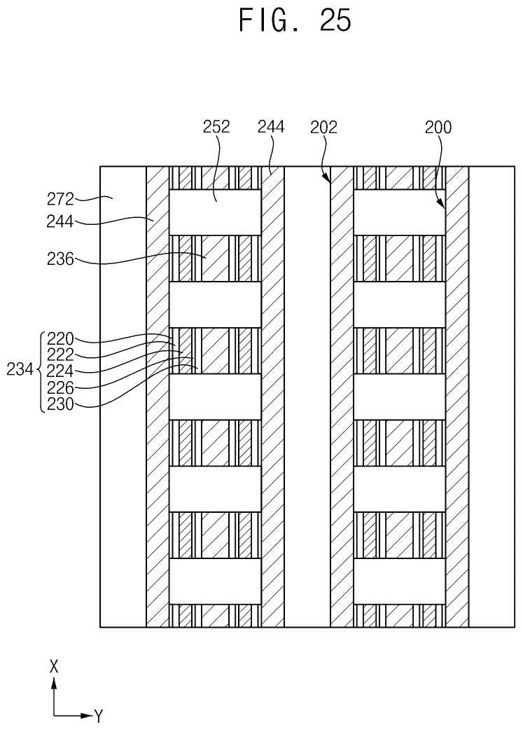

FIG. 24 is a perspective view illustrating a vertical semiconductor device according to example embodiments. FIG. 25 is a plan view illustrating a vertical semiconductor device according to example embodiments.

The vertical semiconductor device may be the same as the vertical semiconductor device described with reference to FIG. 1, except for a shape of a channel structure in a memory cell. Therefore, redundant descriptions are omitted.

Referring to FIGS. 24 and 25, a source line 102 may be on the substrate 100.

A stacked structure in which insulation layer patterns 110a and gate patterns 244 are alternately and repeatedly stacked may be disposed on the source line 102. Each of the gate patterns 244 may extend in the first direction X. The gate pattern may as a word line of memory cells.

A second trench 200 and a third trench 202 extending in the first direction X may pass through the stacked structure. The second and third trenches 200 and 202 may be alternately arranged in the second direction Y. Between the stacked structures arranged in the second direction Y, the second trench 200 or the third trench 202 may be disposed.

A plurality of channel structures 234 extending in the vertical direction Z from an uppermost insulation layer pattern 110a to an upper portion of the source line 102 may be formed in the second trench 200. Each of the channel structures 234 may have a pillar shape. The plurality of channel structures 234 may be spaced apart from each other in the first direction X in the second trench 200.

In the second trench 200, a first separation pattern 252 may be disposed between the channel structures 234. The first separation pattern 252 may include an insulation material.

A second separation pattern 272 may be disposed in the third trench 202. The second separation pattern 272 may fill the third trench 202. The second separation pattern 272 may extend in the first direction. The second separation pattern 272 may include an insulation material.

The channel structure 234 may include a first insulation structure 232, a channel layer 230, a first interface insulation layer 226, a ferroelectric layer 224, a trap nitride layer 222, and a second interface insulation layer 220.

In the channel structure 234, the first insulation structure 232 may have a rectangular pillar shape contacting an upper surface of the source line 102.

The channel layer 230 may surround both sidewalls facing in the second direction Y and a bottom of the first insulation structure 232. The channel layer 230 may have a U-shape, in a cross-sectional view. The channel layer 230 may include a first sidewall and a second sidewall facing to each other in the second direction Y and a bottom surface connecting lower portions of the first and second sidewalls.

The first interface insulation layers 226 may be on the first and second sidewalls of the channel layer 230, respectively. The first interface insulation layer 226 may include, e.g., silicon oxide or a metal oxide having a high dielectric constant.

The ferroelectric layers 224 may be on facing sidewalls of the first interface insulation layers 226, respectively.

The trap nitride layers 222 may be on facing sidewalls of the ferroelectric layers 224, respectively. The trap nitride layer 222 may contact the ferroelectric layer 224. The trap nitride layer 222 may include, e.g., silicon oxynitride or silicon nitride.

Concentrations of silicon included in the trap nitride layer 222 may vary depending on position within the trap nitride layer 222. The inner portion of the trap nitride layer 222 adjacent to the ferroelectric layer 224 may have a relatively high silicon concentration. The silicon concentration within the trap nitride layer pattern 122a may gradually decrease with distance (e.g., as distance increases) from the ferroelectric layer 124.

The second interface insulation layers 220 may be on facing sidewalls of the trap nitride layers 222, respectively.

The first interface insulation layer 226, the ferroelectric layer 224, the trap nitride layer 222, and the second interface insulation layer 220 may be sequentially stacked on each of the first and second sidewalls of the channel layer 230.

The gate pattern 244 may contact sidewalls of the channel structure 234 and the first separation pattern 252, and may extend in the first direction X. Both gate patterns 244 facing each other in the second direction Y may be disposed on one channel layer 230 having the U-shape. The gate patterns 244 may be spaced apart from each other in the vertical direction.

The gate pattern 244 may contact the second interface insulation layer 220 included in the channel structure 234.

An upper conductive pattern 236 may be on the first insulation structure 232, and may contact an upper sidewall of the channel layer 230. The upper conductive pattern 236 may serve as a bit line pad.

An upper insulating interlayer may be on the stacked structure, the channel structure 234, and the first insulation structure 232.

A bit line contact may pass through the upper insulating interlayer, and may contact the upper conductive pattern 236. A bit line may be disposed on the upper insulating interlayer and the bit line contact.

As described above, the first interface insulation layer 226, the ferroelectric layer 224, the trap nitride layer 222, the second interface insulation layer 220, and the gate pattern 244 may be formed on each of the first sidewall and the second sidewall of the channel layer 230. Accordingly, two memory cells may be formed on one channel layer 230 at the same vertical level.

The vertical semiconductor device according to example embodiments may be used as memories included in electronic products such as a mobile device, a memory card, and a computer.

While the present inventive concepts have been shown and described with reference to example embodiments thereof, it will be understood by those of ordinary skill in the art that various changes in form and details may be made thereto without departing from the scope of the present inventive concepts as set forth by the following claims.

What is claimed is:

1. A semiconductor device, comprising:
a channel layer on a substrate;
a first interface insulation layer and a ferroelectric layer sequentially stacked on the channel layer;
a nitride charge trapping layer contacting the ferroelectric layer, the nitride charge trapping layer including at least silicon and nitrogen; and
a gate pattern disposed on the nitride charge trapping layer,
wherein the nitride charge trapping layer has a concentration of silicon that varies depending on a position within the nitride charge trapping layer.

2. The semiconductor device of claim 1, wherein the nitride charge trapping layer includes silicon nitride or silicon oxynitride.

3. The semiconductor device of claim 1, wherein a portion of the nitride charge trapping layer adjacent to an interface between the nitride charge trapping layer and the ferroelectric layer has a highest silicon concentration within the nitride charge trapping layer.

4. The semiconductor device of claim 3, wherein the silicon included in the portion of the nitride charge trapping layer adjacent to the interface reduces loss of trapped charges from the nitride charge trapping layer to the ferroelectric layer.

5. The semiconductor device of claim 1, wherein a silicon concentration within the nitride charge trapping layer gradually decreases as distance from the ferroelectric layer increases.

6. The semiconductor device of claim 1, wherein the nitride charge trapping layer includes a first nitride charge trapping sub-layer contacting the ferroelectric layer and having a first silicon concentration, and a second nitride charge trapping sub-layer disposed on the first nitride charge trapping sub-layer and having a second silicon concentration lower than the first silicon concentration.

7. The semiconductor device of claim 1, further comprising a second interface insulation layer between the nitride charge trapping layer and the gate pattern.

8. The semiconductor device of claim 1, wherein the first interface insulation layer, the ferroelectric layer, and the nitride charge trapping layer are stacked on a sidewall of the channel layer in a horizontal direction parallel to a surface of the substrate.

9. The semiconductor device of claim 1, wherein a thickness of the ferroelectric layer is greater than a thickness of the nitride charge trapping layer.

10. The semiconductor device of claim 1, wherein a distance between the ferroelectric layer and the channel layer is less than a distance between the nitride charge trapping layer and the channel layer.

11. A semiconductor device, comprising:
a source line on a substrate;
a channel layer on the source line;
a first interface insulation layer and a ferroelectric layer sequentially stacked on sidewalls of the channel layer;
a nitride charge trapping layer contacting a surface of the ferroelectric layer and including at least silicon and nitrogen;
a second interface insulation layer on a surface of the nitride charge trapping layer; and
a plurality of gate patterns on a surface of the second interface insulation layer, the plurality of gate patterns being spaced apart from each other in a vertical direction perpendicular to an upper surface of the substrate,
wherein the nitride charge trapping layer has a concentration of silicon that varies depending on a position within the nitride charge trapping layer.

12. The semiconductor device of claim 11, wherein a portion of the nitride charge trapping layer adjacent to an interface between the nitride charge trapping layer and the ferroelectric layer has a highest silicon concentration within the nitride charge trapping layer.

13. The semiconductor device of claim 11, wherein a silicon concentration within the nitride charge trapping layer gradually decreases as distance from the ferroelectric layer increases.

14. The semiconductor device of claim 11, wherein the nitride charge trapping layer includes a first nitride charge trapping sub-layer contacting the ferroelectric layer and having a first silicon concentration, and a second nitride charge trapping sub-layer disposed on the first nitride charge trapping sub-layer and having a second silicon concentration lower than the first silicon concentration.

15. The semiconductor device of claim 11, further comprising an insulation pillar on the source line,
wherein the channel layer surrounds sidewalls and a bottom of the insulation pillar.

16. The semiconductor device of claim 15, wherein a stacked structure including the insulation pillar, the channel layer, the first interface insulation layer, the ferroelectric layer, the nitride charge trapping layer and the second interface insulation layer has a pillar shape.

17. The semiconductor device of claim 11, wherein at least one of the ferroelectric layer, the nitride charge trapping layer, and the second interface insulation layer is arranged to face one of the gate patterns in a horizontal direction parallel to the surface of the substrate, and has a ring shape.

18. The semiconductor device of claim 11, wherein a thickness of the ferroelectric layer is greater than a thickness of the nitride charge trapping layer.

19. The semiconductor device of claim 11, wherein a distance between the ferroelectric layer and the channel layer is less than a distance between the nitride charge trapping layer and the channel layer.

20. A semiconductor device, comprising:
a source line on a substrate;
a channel layer on the source line, the channel layer including a vertical extension extending in a vertical direction perpendicular to an upper surface of the substrate;
a first interface insulation layer and a ferroelectric layer sequentially stacked on at least a portion of a sidewall of the vertical extension of the channel layer in a horizontal direction parallel to the upper surface of the substrate;
a nitride charge trapping layer contacting a surface of the ferroelectric layer, and including at least silicon and nitrogen;
a second interface insulation layer on a surface of the nitride charge trapping layer;
a plurality of gate patterns on the surface of the second interface insulation layer, the plurality of gate patterns being spaced apart from each other in a vertical direction perpendicular to the upper surface of the substrate; and
an insulation layer pattern between the plurality of gate patterns in the vertical direction,
wherein a portion of the nitride charge trapping layer adjacent to an interface between the nitride charge trapping layer and the ferroelectric layer has a highest silicon concentration within the nitride charge trapping layer, and
wherein a silicon concentration within the nitride charge trapping layer gradually decreases as distance from the ferroelectric layer increases.
